(19) United States
(12) Patent Application Publication
(10) Pub. No.: US 2018/0090376 A1
(43) Pub. Date: Mar. 29, 2018

(54) ARRAY SUBSTRATE AND METHOD OF MANUFACTURING THE SAME, DISPLAY PANEL AND DISPLAY DEVICE

(71) Applicants: BOE TECHNOLOGY GROUP CO., LTD., Beijing (CN); HEFEI XINSHENG OPTOELECTRONICS TECHNOLOGY CO., LTD., Hefei, Anhui (CN)

(72) Inventors: Cong Tan, Beijing (CN); Kai Wang, Beijing (CN); Bo Zhang, Beijing (CN); Chengyong Zhan, Beijing (CN)

(21) Appl. No.: 15/515,140

(22) PCT Filed: Jul. 1, 2016
(86) PCT No.: PCT/CN2016/088070

§ 371 Date: Mar. 28, 2017

(30) Foreign Application Priority Data
Mar. 7, 2016 (CN) 201610127882.7

(51) Int. Cl. H01L 21/77; G02F 1/1333; H01L 27/12

(52) U.S. Cl. CPC H01L 21/77; G02F 2001/133311; H01L 27/12; G02F 1/133308

(57) ABSTRACT

The present disclosure provides an array substrate and a method of manufacturing the same, a display panel and a display device. The array substrate is provided, on surface(s) of an organic material layer, with a thermally conductive layer, which functions to conduct heat and thus reduce expansion of the organic material, thereby avoiding the bonding force between the organic material layer and a gate insulating layer and a passivation layer from being affected by the expansion of the organic material and avoiding formation of any gap therebetween.

### CROSS-REFERENCE TO RELATED APPLICATIONS

This application is a Section 371 National Stage Application of International Application No. PCT/CN2016/088070, filed on Jul. 1, 2016, entitled “ARRAY SUBSTRATE AND METHOD OF MANUFACTURING THE SAME, DISPLAY PANEL AND DISPLAY DEVICE”, which claims priority to Chinese Application No. 201610127882.7, filed on Mar. 7, 2016, incorporated herein by reference in their entirety.

### BACKGROUND

### 1. Technical Field

The present disclosure relates to display technique field, and particularly to an array substrate and a method of manufacturing the same, a display panel and a display device.

### 2. Description of the Related Art

In order to reduce power consumption, a conventional display panel is provided with an organic material layer between a gate insulating layer and a passivation layer of a display substrate. When the conventional display product with the organic material layer is tested under high humidity at high temperature, water vapor tends to enter a display region from an edge of the display panel and form a gas bubble, thereby rendering failure of the display product during a reliability test. Specifically, in a situation of high humidity and high temperature, the organic material film tends to expand to cause bonding between the organic material layer and the gate insulating layer and the passivation layer to be degraded such that a gap may be generated between the organic material layer and the gate insulating layer and the passivation layer and water vapor may enter the display region of the display panel through the gap and form the gas bubble.

### SUMMARY

Embodiments of the present disclosure provide an array substrate including a base substrate, the base substrate comprising a display region and a sealant coating region and being provided thereon with thin film transistors and an organic material layer, the organic material layer being provided in both the display region and the sealant coating region. A thermally conductive layer is provided on a first surface, which is located apart away from the base substrate, and/or on a second surface, which is located close to the base substrate, of a portion of the organic material layer located within the sealant coating region.

Optionally, material to form the thermally conductive layer includes metal material.

Optionally, the material to form the thermally conductive layer includes one or more from the following: golden, silver, copper, aluminum, titanium, chromium, molybdenum, cadmium, nickel and cobalt.

Optionally, the thermally conductive layer is a plate-like metal layer.

Optionally, the thermally conductive layer comprises a plurality of metal strips.

Optionally, when the thermally conductive layer is located on the second surface, the thermally conductive layer is configured such that the thermally conductive layer and a data line are alternately arranged and are spaced apart from each other.

Embodiments of the present disclosure provide a display panel including the above described array substrate.

Embodiments of the present disclosure further provide a display device including the above described display panel.

Embodiments of the present disclosure further provide a method of manufacturing an array substrate, the method including:

forming thin film transistors on a base substrate, the base substrate comprising a display region and a sealant coating region;

forming an organic material layer over the display region and the sealant coating region; and

forming a thermally conductive layer on a first surface, which is located apart away from the base substrate, and/or on a second surface, which is located close to the base substrate, of a portion of the organic material layer located within the sealant coating region.

Optionally, material to form the thermally conductive layer includes metal material.

Optionally, forming a thermally conductive layer on a first surface, which is located apart away from the base substrate, of a portion of the organic material layer located within the sealant coating region comprises:

forming a metal film on the first surface;

coating photoresist over the metal film;

forming a photoresist remained area and a photoresist removed area by exposing the photoresist through a mask, the photoresist remained area corresponding to an area where a pattern of the thermally conductive layer is to be formed, the photoresist removed area corresponding to remaining areas excluding the area where the pattern of the thermally conductive layer is to be formed; and

forming the thermally conductive layer by etching the metal film.

Optionally, forming the thin film transistors on the base substrate includes:

forming gate electrodes on the base substrate;

forming an active layer over the gate electrodes; and

forming source electrodes and drain electrodes on the active layer;

posterior to forming the gate electrodes on the base substrate and prior to forming the active layer over the gate electrodes, the method further comprises:

forming a gate insulating layer on the gate electrodes;

forming an active layer over the gate electrodes comprises:

forming an active layer on the gate insulating layer;

forming an organic material layer over the display region and the sealant coating region comprises:

forming an organic material layer over the source electrodes and the drain electrodes; and

posterior to forming the organic material layer over the source electrodes and the drain electrodes, the method comprises:

forming a passivation layer over the organic material layer.

Optionally, when forming the thermally conductive layer on the second surface, which is close to the base substrate, of the portion of the organic material layer located within the sealant coating region, the thermally conductive layer is configured such that the thermally conductive layer and a data line are alternately arranged and are spaced apart from each other.

### BRIEF DESCRIPTION OF THE DRAWINGS

FIG. 1 is a structural schematic view of an array substrate according to an embodiment of the present disclosure;

FIG. 2 is a structural schematic view illustrating a transistor in the array substrate provided by the embodiment of the present disclosure;

FIG. 3 is a structural schematic view of an array substrate according to another embodiment of the present disclosure;

FIG. 4 is a structural schematic view of an array substrate according to a further embodiment of the present disclosure;

FIG. 5 is a structural schematic view of a display panel according to a still further embodiment of the present disclosure;

FIG. 6 is a structural schematic view of another display panel according to the still further embodiment of the present disclosure;

FIG. 7 is a structural schematic view of a further display panel according to the still further embodiment of the present disclosure; and

FIG. 8 is a flow chart of a method of manufacturing an array substrate according to an embodiment of the present disclosure.

### DETAILED DESCRIPTION OF THE EMBODIMENTS

An array substrate and a method of manufacturing the same, a display panel and a display device provided by embodiments of the present disclosure will be described as follows in detail in conjunction with the accompanying drawings in order to make those skilled in the art to better understand the technique schemes of the present disclosure.

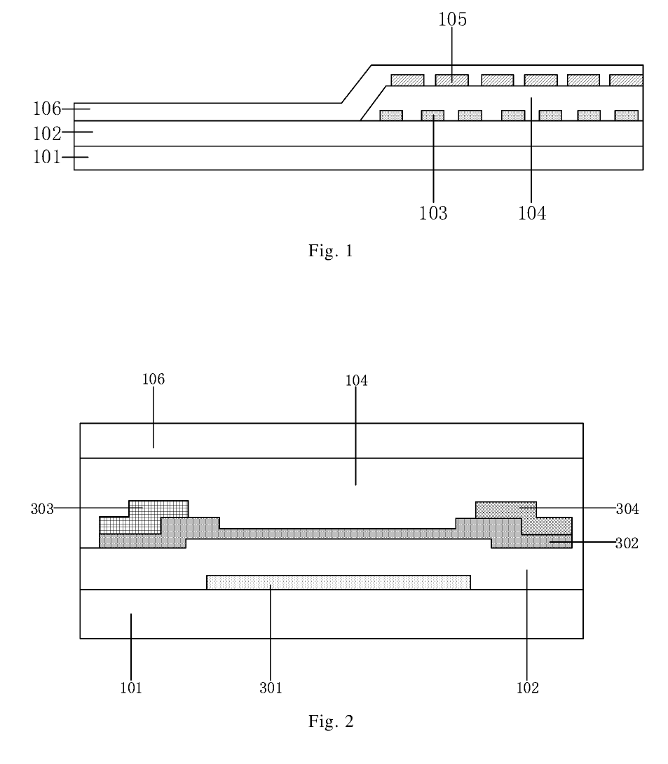

FIG. 1 is a structural schematic view of an array substrate provided by an embodiment of the present disclosure. As shown in FIG. 1, the array substrate includes a base substrate 101 including a display region and a sealant coating region. The base substrate 101 is provided with thin film transistors and an organic material layer 104 and the organic material layer 104 is disposed in the display region and the sealant coating region. The thin film transistors are arranged in the display region. A thermally conductive layer 105 is provided on a first surface, which is apart away from the base substrate 101, of a portion of the organic material layer 104 that is located in the sealant coating region. Optionally, a passivation layer 106 is provided over the organic material layer 104. As shown in FIG. 1, the organic material layer 104 is arranged between a gate insulating layer 102 and the passivation layer 106. The array substrate may further include data lines 103, which are arranged on a second surface of the organic material layer 104 close to the base substrate 101. The thermally conductive layer 105 is configured to conduct heat so as to decrease expansion of the organic material when it is heated, thereby avoiding bonding force between the organic material layer and the gate insulating layer and the passivation layer from being affected by expansion of the organic material and thus avoiding final formation of any gap therebetween. In the array substrate according to this embodiment of the present disclosure, any gap between these layers may be avoided and thus a situation where water vapor would otherwise enter the display region of the display panel through the gaps during testing under high humidity and high pressure at high temperature can be avoided, thereby avoiding formation of gas bubble in the display region and thus improving performance of high temperature and high humidity resistance and finally increasing reliability and service life of the display device under severe conditions.

In the embodiment, the organic material layer 104 may be made of a cellulose derivative material, a polysulfone material, a polyamide material, a polyimide material, a polyester material, a polyolefin material, a silicon-containing polymer or a fluorine-containing polymer material, and the thermally conductive layer 105 may be made of a metal material. Preferably, the thermally conductive layer 105 may be made of one or more of the following materials including golden, silver, copper, aluminum, titanium, chromium, molybdenum, cadmium, nickel and cobalt. Optionally, the thermally conductive layer 105 may be configured as a plate-like metal layer. In an embodiment, the thermally conductive layer 105 includes a plurality of metal strips, so as to save material and reduce product cost.

FIG. 2 is a structural schematic view of a thin film transistor in the array substrate provided according to the embodiment of the present disclosure. As shown in FIG. 2, the thin film transistor includes a gate electrode 301, an active layer 302, a source electrode 303 and a drain electrode 304. The gate electrode 301 is provided on the base substrate 101. A gate insulating layer 102 is arranged on the gate electrode 301. The active layer 302 is provided on the gate insulating layer 102. The source electrode 303 and the drain electrode 304 are arranged on the active layer 302. The organic material layer 104 is arranged over the source electrode 303 and the drain electrode 304, and a passivation layer 106 is provided over the organic material layer 104.

The array substrate according to the embodiment is provided with the thermally conductive layer on a surface, apart away from the base substrate, of the organic material layer. The thermally conductive layer functions to conduct heat and thus avoid the bonding force between the organic material layer and the gate insulating layer and the passivation layer from being affected by expansion of the organic material, thereby finally avoiding formation of any gap therebetween. In the array substrate according to the embodiment, any gap may be avoided from being formed between the layers and thus a situation where water vapor would otherwise enter the display region of the display panel through the gap during testing under high humidity and high pressure at high temperature can be avoided, thereby avoiding formation of gas bubble in the display region, improving performance of high temperature and high humidity resistance of the organic material layer and finally increasing reliability and service life of the display device in severe environment.

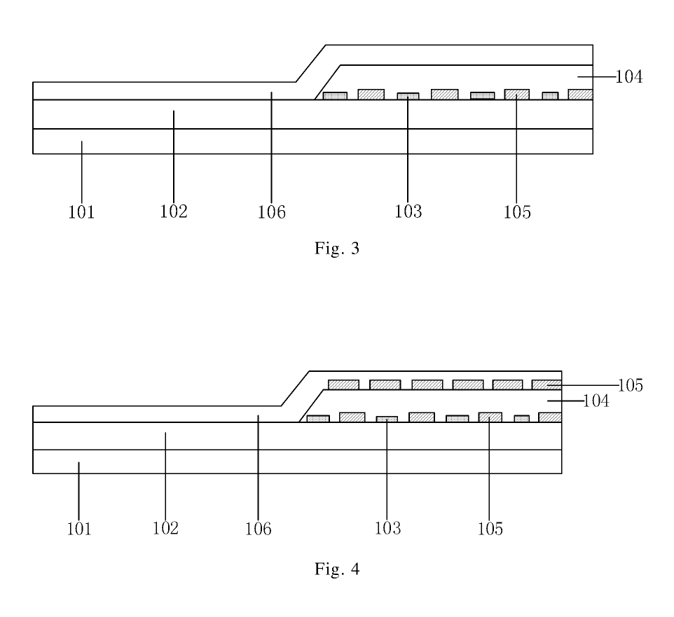

FIG. 3 is a structural schematic view of an array substrate according to another embodiment of the present disclosure. As shown in FIG. 3, the array substrate includes a base substrate 101 and the base substrate 101 includes a display region and a sealant coating region. The base substrate 101 is provided with thin film transistors and an organic material layer 104, the organic material layer 104 is provided in the display region and the sealant coating region, and the thin film transistors are provided in the display region. The thermally conductive layer 105 is arranged on or in a second surface, which is located adjacent to the base substrate 101, of a portion of the organic material layer 104 located in the sealant coating region. Optionally, a passivation layer 106 is provided over the organic material layer 104. As shown in FIG. 3, the organic material layer 104 is provided between the gate insulating layer 102 and the passivation layer 106. The array substrate further includes data lines 103 arranged on or in the second surface, which is close to the base substrate 101, of the organic material layer 104. The thermally conductive layer 105 is configured to conduct heat so as to decrease expansion of the organic material when it is heated, thereby avoiding bonding force between the organic material layer and the gate insulating layer and the passivation layer from being affected by expansion of the organic material and thus avoiding formation of gap therebetween. In the array substrate according to the embodiment of the present disclosure, any gap may be avoided from being formed between these layers and thus a situation where water vapor would otherwise enter the display region of the display panel through the gap during testing under high humidity and high pressure at high temperature can be avoided, thereby avoiding formation of gas bubble in the display region and thus improving performance of high temperature and high humidity resistance and finally increasing reliability and service life of the display device under severe conditions.

In the embodiment, the thermally conductive layer 105 includes a plurality of metal strips. The metal stripes and the data lines 103 are alternately arranged so as to save material and reduce product cost.

Structures of other portions of the array substrate in the embodiment are similar to those in the above embodiment. Specifically, as shown in FIG. 2, the thin film transistor in the array substrate includes a gate electrode 301, an active layer 302, a source electrode 303 and a drain electrode 304. The gate electrode 301 is provided on the base substrate 101 and a gate insulating layer 102 is provided on the gate electrode 301. The active layer 302 is provided on the gate insulating layer 102, and the source electrode 303 and the drain electrode 304 are provided on the active layer 302. The organic material layer 104 is arranged over the source electrode 303 and the drain electrode 304. The passivation layer 106 is arranged over the organic material layer 104.

In the array substrate according to the embodiment of the present disclosure, the thermally conductive layer provided on or in the surface, which is located close to the base substrate, of the organic material layer functions to conduct heat so as to decrease expansion of the organic material when it is heated, thereby avoiding bonding force between the organic material layer and the gate insulating layer and the passivation layer from being affected by expansion of the organic material and thus formation of final gap therebetween. In the array substrate according to this embodiment, any gap may be prevented from being formed between these layers and thus a situation where water vapor would otherwise enter the display region of the display panel through the gap during testing under high humidity and high pressure at high temperature can be avoided, thereby avoiding formation of gas bubble in the display region and thus improving performance of high temperature and high humidity resistance and finally increasing reliability and service life of the display device under severe conditions.

FIG. 4 is a structural schematic view of an array substrate according to a further embodiment of the present disclosure. As shown in FIG. 4, the array substrate includes a base substrate 101 and the base substrate 101 includes a display region and a sealant coating region. The base substrate 101 is provided with thin film transistors and an organic material layer 104, the organic material layer 104 is provided in the display region and the sealant coating region, and the thin film transistors are provided in the display region. A thermally conductive layer 105 is arranged on or in a first surface, which is apart away from the base substrate 101, and on or in a second surface, which is close to the base substrate 101, of a portion of the organic material layer 104 located in the sealant coating region. Optionally, a passivation layer 106 is provided over the organic material layer 104. As shown in FIG. 4, the organic material layer 104 is provided between the gate insulating layer 102 and the passivation layer 106. The array substrate further include a data line 103 arranged on or in the second surface, which is close to the base substrate 101, of the organic material layer 104. The thermally conductive layer 105 is configured to conduct heat so as to decrease expansion of the organic material when it is heated, thereby avoiding bonding force between the organic material layer and the gate insulating layer and the passivation layer from being affected by expansion of the organic material and finally avoiding formation of any gap therebetween. In the array substrate according to this embodiment of the present disclosure, any gap may be prevented from being formed between these layers and thus a situation where water vapor would otherwise enter the display region of the display panel through the gap during testing under high humidity and high pressure at high temperature can be avoided, thereby avoiding formation of any gas bubble in the display region and thus improving performance of high temperature and high humidity resistance and finally increasing reliability and service life of the display device under severe conditions.

In this embodiment, the thermally conductive layer 105 arranged on or in the second surface includes a plurality of metal strips. The metal strips and the data lines 103 are alternately arranged so as to save material and reduce product cost. This embodiment is configured such that the upper and lower surface of the organic material layer 104 are both provided with the thermally conductive layers 105, and thus may, in a more effective manner, conduct heat, reduce expansion of the organic material when it is heated, thereby avoiding bonding force between the organic material layer and the gate insulating layer and the passivation layer from being affected by expansion of the organic material and finally avoiding formation of any gap therebetween.

Structures of other portions of the array substrate in this embodiment are similar to those in embodiment 1. Specifically, as shown in FIG. 2, the thin film transistor in the array substrate includes a gate electrode 301, an active layer 302, a source electrode 303 and a drain electrode 304. The gate electrode 301 is provided on the base substrate 101 and a gate insulating layer 102 is provided on the gate electrode 30. The active layer 302 is provided on the gate insulating layer 102, and the source electrode 303 and the drain electrode 304 are provided on the active layer 302. The organic material layer 104 is arranged over the source electrode 303 and the drain electrode 304. The passivation layer 106 is arranged over the organic material layer 104.

In the array substrate according to this embodiment of the present disclosure, the thermally conductive layers provided both on or in the surface, which is close to the base substrate, and the surface, which is apart away from the base substrate, of the organic material layer function to conduct heat so as to decrease expansion of the organic material when they are heated, thereby avoiding bonding force between the organic material layer and the gate insulating layer and the passivation layer from being affected by expansion of the organic material and finally avoiding formation of any gap therebetween. In the array substrate according to this embodiment, any gap may be prevented from being formed between these layers and thus a situation where water vapor would otherwise enter the display region of the display panel through the gap during testing under high humidity and high pressure at high temperature can be avoided, thereby avoiding formation of any gas bubble in the display region and thus improving performance of high temperature and high humidity resistance and finally increasing reliability and service life of the display device under severe conditions.

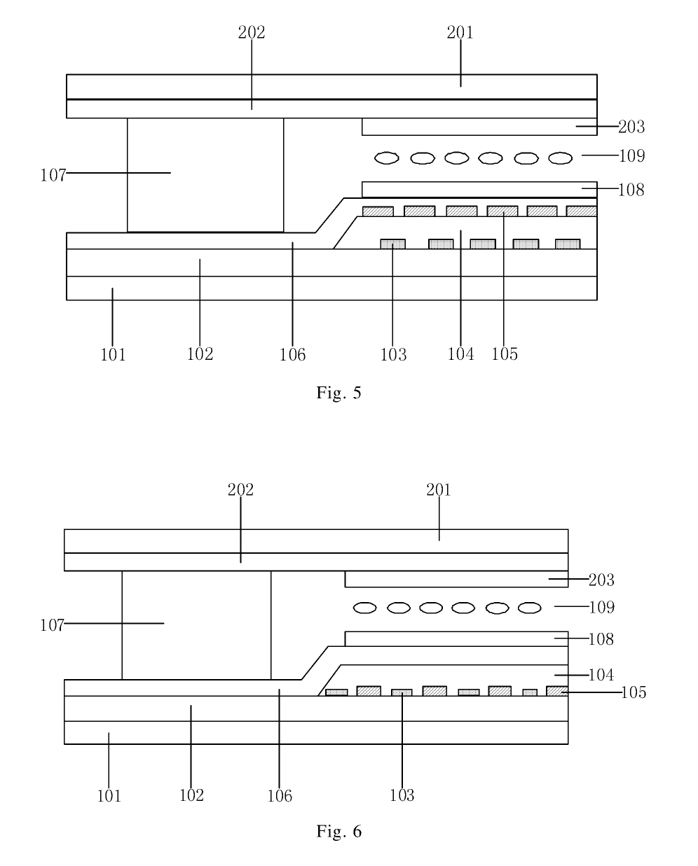

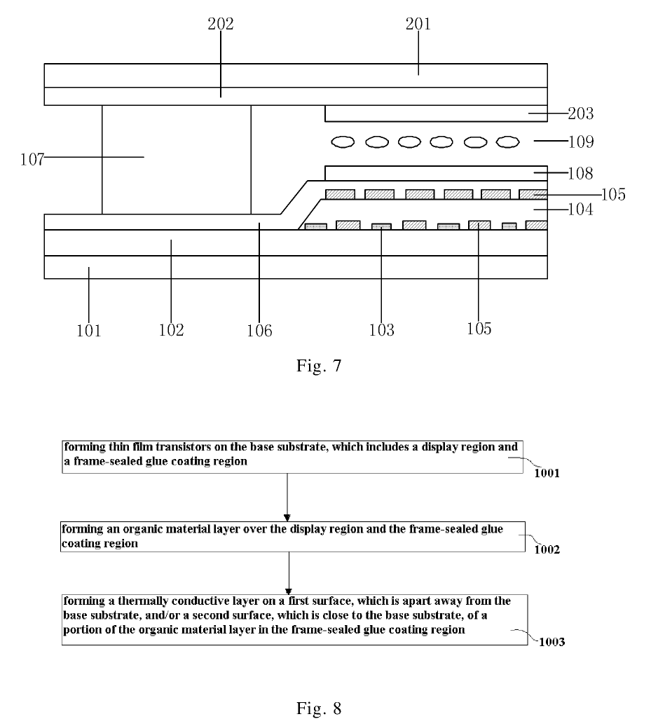

FIG. 5 is a structural schematic view of a display panel according to a still further embodiment of the present disclosure, FIG. 6 is a structural schematic view of a further display panel according to the still further embodiment of the present disclosure and FIG. 7 is a structural schematic view of another display panel according to embodiment 4 of the present disclosure. As shown in FIGS. 5-7, the display panel includes a color film substrate and the array substrate according to any one of above embodiments. The color film substrate and the array substrate are securely coupled with each other through a sealant 107. The display panel shown in FIG. 5 includes the array substrate according to the above embodiment, the display panel shown in FIG. 6 includes the array substrate according to the above embodiment, and the display panel shown in FIG. 7 includes the array substrate according to the above embodiment. The detailed description of the array substrate may be referred to the above embodiments and is not repeatedly described.

Referring to FIGS. 5-7, the color film substrate includes a base substrate 201, on which a black matrix 202 is provided. An upper alignment layer 203 is provided on the black matrix 202 and a lower alignment layer 108 is provided on the passivation layer 106. A liquid crystal layer 109 is provided between the alignment layer 203 and the lower alignment layer 108.

In the display panel according to the embodiments, the thermally conductive layer is provided on or in a surface of the organic material layer and functions to conduct heat so as to decrease expansion of the organic material when being heated, thereby avoiding the bonding force between the organic material layer and the gate insulating layer and the passivation layer from being affected by expansion of the organic material and finally avoiding formation of gap therebetween. In the display panel according to the embodiments, any gap may be avoided from being formed between the layers and thus a situation where water vapor would otherwise enter the display region of the display panel through the gap during testing under high humidity and high pressure at high temperature can be avoided, thereby avoiding formation of any gas bubble in the display region, improving performance of high temperature and high humidity resistance of the organic material layer and increasing reliability and service life of the display device in severe environment.

An embodiment of the disclosure provides a display device including the array substrate according to any one of the above embodiments. The detailed description of the array substrate may be referred to the above embodiments and is not repeatedly described.

In the display device according to this embodiment, the thermally conductive layer is provided on or in a surface of the organic material layer of the array substrate and functions to conduct heat so as to decrease expansion of the organic material when being heated, thereby avoiding the bonding force between the organic material layer and the gate insulating layer and the passivation layer from being affected by expansion of the organic material and finally avoiding occurrence of any gap therebetween. In the display device according to this embodiment, any gap may be avoided from being formed between the layers and thus a situation where water vapor would otherwise enter the display region of the display panel through the gap during testing under high humidity and high pressure at high temperature can be avoided, thereby avoiding formation of any gas bubble in the display region, improving performance of high temperature and high humidity resistance of the organic material layer and finally increasing reliability and service life of the display device in severe environment.

FIG. 8 is a flow chart of a method of manufacturing an array substrate according to an embodiment of the present disclosure. As shown in FIG. 8, the method of manufacturing the array substrate includes:

step 1001: forming thin film transistors on a base substrate, which includes a display region and a sealant coating region;

step 1002: forming an organic material layer and a thermally conductive layer over the display region and the sealant coating region; and

wherein the thermally conductive layer is formed on or in a second surface, which is located close to the base substrate, of a portion of the organic material layer located within the sealant coating region and/or the thermally conductive layer is formed on or in a first surface, which is apart away from the base substrate, of a portion of the organic material layer located in the sealant coating region.

Referring to FIG. 1, the thermally conductive layer 105 is formed on the first surface of the organic material layer 104, which is the surface of the organic material layer 104 that is apart away from the base substrate. Referring to FIG. 3, the thermally conductive layer 105 is formed on or in the second surface of the organic material layer 104, which is the surface of the organic material layer 104 that is close to the base substrate. In this configuration, the organic material layer 104 and the data line are alternately arranged and spaced from each other. It is noted that the formation of the thermally conductive layer on or in the second surface may be performed by common methods in related art. For example, the thermally conductive layer 105 may be firstly formed, and the organic material layer 104 may be then formed, such as covering the thermally conductive layer 105 by the organic material layer 104. Referring to FIG. 4, the thermally conductive layers 105 are formed both on or in the first surface and the second surface of the organic material layer 104. Preferably, a material to form the thermally conductive layer 105 includes a metal material. Further preferably, the material to form the thermally conductive layer 105 includes one or more of golden, silver, copper, aluminum, titanium, chromium, molybdenum, cadmium, nickel and cobalt.

Optionally, forming the thermally conductive layer on or in the first surface, which is apart away from the base substrate, of a portion of the organic material layer located in the sealant coating region, comprises: forming a metal film on or in the first surface; coating photoresist on the metal film; forming a photoresist remained area and a photoresist removed area by exposing the photoresist through a mask and by development of the photoresist, the photoresist remained area corresponding to an area where a pattern of the thermally conductive layer is to be formed and the photoresist removed area corresponding to remaining areas excluding the area where a pattern of the thermally conductive layer is to be formed; and forming the thermally conductive layer by etching the metal film.

In this embodiment, the organic material layer 104 and the thermally conductive layer 105 may be formed through a single patterning process. Specifically, an organic material film is formed over the display region and the sealant coating region. A metal film is formed on or in the first surface of the organic material film that is apart away from the base substrate. A photoresist is coated on the metal film and is exposed through a half tone mask and developed to obtain a photoresist remained area, a photoresist half remained area and a photoresist removed area. The photoresist remained area corresponds to an area where a pattern of the thermally conductive layer is to be formed, the photoresist removed area corresponds to an area where a pattern of the organic material layer is to be formed and the photoresist half remaining area corresponds to remaining areas excluding the area where a pattern of the thermally conductive layer is to be formed and the area where a pattern of the organic material layer is to be formed. The organic material film and the metal film are etched to form the organic material layer 104. The photoresist in the photoresist half remained area is removed by an ashing process and the metal film is etched to form the thermally conductive layer 105. The organic material layer 104 and the thermally conductive layer 105 are obtained through a single patterning process by means of the half tone mask, thereby reducing process steps, improving producing efficiency and reducing product cost.

Referring to FIG. 2, the method of manufacturing the array substrate may include: forming gate electrodes 301 on the base substrate 101, forming a gate insulating layer 102 on the gate electrodes 301, forming an active layer 302 on the gate insulating layer 102, forming the source electrodes 303 and the drain electrodes 304 on the active layer 302, forming the organic material layer 104 over the source electrodes 303 and the drain electrodes 304, and forming the passivation layer 106 over the organic material layer 104.

In the method of manufacturing the array substrate according to this embodiment, the array substrate is configured, on the surface(s) of the organic material layer, with the thermally conductive layer, which functions to conduct heat and thus may reduce expansion of the organic material when being heated, thereby avoiding affection on the bonding force between the organic material layer and the gate insulating layer and passivation layer by the expansion of the organic material and avoiding formation of any gap between the organic material layer and the gate insulating layer and passivation layer. With the method according to this embodiment, any gap may be prevented from being formed between the layers and thus a situation where water vapor would otherwise enter the display region of the display panel through the gap during testing under high humidity and high pressure at high temperature can be avoided, thereby avoiding formation of any gas bubble in the display region and thus improving performance of high temperature and high humidity resistance and finally increasing reliability and service life of the display device under severe conditions.

It is understood that the above embodiments are merely used as exemplary embodiments intended to illustrate the principle of the present disclosure. The present disclosure, however, is not limited to those. It will be understood by those skilled in the art that various changes and modifications may be made therein without departing from the spirit of the present invention, and should be regarded as falling with the scope of the present invention.

1. An array substrate comprising a base substrate, the base substrate comprising a display region and a sealant coating region and being provided thereon with thin film transistors and an organic material layer, the organic material layer being provided in both the display region and the sealant coating region, wherein, a thermally conductive layer is provided on or in a first surface, which is located apart and away from the base substrate, and/or on a second surface, which is located close to the base substrate, of a portion of the organic material layer located within the sealant coating region.

2. The array substrate according to claim 1, wherein, material to form the thermally conductive layer includes metal material.

3. The array substrate according to claim 2, wherein, the material to form the thermally conductive layer includes one or more from the following: gold, silver, copper, aluminum, titanium, chromium, molybdenum, cadmium, nickel and cobalt.

4. The array substrate according to claim 2, wherein, the thermally conductive layer is a plate-like metal layer.

5. The array substrate according to claim 2, wherein, the thermally conductive layer comprises a plurality of metal strips.

6. The array substrate according to claim 1, wherein, the thermally conductive layer is located on or in the second surface, and the thermally conductive layer is configured such that the thermally conductive layer and a data line are alternately arranged and are spaced apart from each other.

7. A display panel comprising the array substrate according to claim 1.

8. A display device comprising the display panel according to claim 7.

9. A method of manufacturing an array substrate, wherein, the method comprises:
forming thin film transistors on a base substrate, the base substrate comprising a display region and a sealant coating region;
forming an organic material layer and a thermally conductive layer over the display region and the sealant coating region; and
wherein, the thermally conductive layer is formed on or in a second surface, which is located close to the base substrate, of a portion of the organic material layer located within the sealant coating region and/or the thermally conductive layer is formed on or in a first surface, which is located apart and away from the base substrate, of a portion of the organic material layer located within the sealant coating region.

10. The method according to claim 9, wherein, material to form the thermally conductive layer includes metal material.

11. The method according to claim 10, wherein, forming a thermally conductive layer on or in a first surface, which is located apart away from the base substrate, of a portion of the organic material layer located within the sealant coating region comprises:
forming a metal film on the first surface;
coating photoresist over the metal film;
forming a photoresist remained area and a photoresist removed area by exposing the photoresist through a mask, the photoresist remained area corresponding to an area where a pattern of the thermally conductive layer is to be formed, the photoresist removed area corresponding to remaining areas excluding the area where the pattern of the thermally conductive layer is to be formed; and
forming the thermally conductive layer by etching the metal film.

12. The method according to claim 9, wherein, forming the thin film transistors on the base substrate comprises:
forming gate electrodes on the base substrate;
forming an active layer over the gate electrodes; and
forming source electrodes and drain electrodes on the active layer;
posterior to forming the gate electrodes on the base substrate and prior to forming the active layer over the gate electrodes, the method further comprises:
forming a gate insulating layer on the gate electrodes;
forming an active layer over the gate electrodes comprises:
forming an active layer on the gate insulating layer;
forming an organic material layer over the display region and the sealant coating region comprises:
forming an organic material layer over the source electrodes and the drain electrodes; and
posterior to forming the organic material layer over the source electrodes and the drain electrodes, the method comprises:
forming a passivation layer over the organic material layer.

13. The method according to claim 9, wherein:
the thermally conductive layer is formed on or in the second surface, which is close to the base substrate, of the portion of the organic material layer located within the sealant coating region, and the thermally conductive layer is configured such that the thermally conductive layer and a data line are alternately arranged and are spaced apart from each other.

14. A display panel comprising the array substrate according to claim 2.

15. A display panel comprising the array substrate according to claim 3.

16. A display panel comprising the array substrate according to claim 4.

17. A display panel comprising the array substrate according to claim 5.

18. A display panel comprising the array substrate according to claim 6.
